(19) United States
(12) Patent Application Publication
(10) Pub. No.: US 2026/0321848 A1
(43) Pub. Date: Oct. 15, 2026

(54) BATTERY ENERGY STORAGE SYSTEM ENCLOSURE FOR SUPPORTING LARGE BATTERY RACKS

(71) Applicant: Fluence Energy, LLC, Arlington, VA (US)

(72) Inventors: Anantha Kumar Hanumaiah, Mandya (IN); Srinivasa ., Bengaluru (IN)

(73) Assignee: Fluence Energy, LLC, Arlington, VA (US)

(21) Appl. No.: 19/641,460

(22) Filed: Apr. 7, 2026

Related U.S. Application Data
(60) Provisional application No. 63/787,222, filed on Apr. 11, 2025.

(51) Int. Cl. H01M 50/251; H01M 50/209; H01M 50/258; H01M 50/291; H05K 7/18

(52) U.S. Cl. CPC H01M 50/251; H01M 50/209; H01M 50/258; H01M 50/291; H05K 7/183; H01M 2220/10

(57) ABSTRACT

A battery energy storage system (BESS) includes at least one BESS enclosure having a main structure, and a rear panel. The main structure includes a base weldment having a front edge, and a rear edge, a pair of opposing side weldments, and a top side weldment having a front edge and a rear edge. A plurality of crossbeams, a plurality of inner panels, and a battery rack are arranged within the main structure. The rear panel includes a bottom edge arranged adjacent to the rear edge of the base weldment, and a top edge of the rear panel arranged adjacent to the rear edge of the top side weldment. At least one of the plurality of crossbeams includes a closed, hollow cross-section. At least one of the plurality of inner panels includes a steel inner insulation panel.

### CROSS-REFERENCE TO RELATED APPLICATIONS

This application claims the benefit of U.S. Provisional Application Number 63/787,222 filed on Feb. 11, 2025, which is hereby incorporated by reference in its entirety.

### INTRODUCTION

The concepts described herein relate generally to energy storage systems, and more specifically, to a battery energy storage system (BESS) enclosure that incorporates battery racks having a larger size and increased weight supported within the BESS enclosure.

Modular battery energy storage systems include multiple individual BESSs interconnected to provide larger modular battery energy storage systems having varied levels of increased storage capacity. Each BESS enclosure includes a battery rack that holds multiple battery modules, supported within the BESS enclosure. Each BESS enclosure can be used to store additional power produced by an external power source during periods of reduced demand and provide that stored power to external power sources during periods of increased demand.

As demand for BESSs having greater storage capacity increases, the overall footprint (size) and battery mass (weight) of the battery rack including the multiple battery modules supported within each BESS enclosure increases respectively. As the overall size and weight of the battery rack including the multiple battery modules increases, the BESS enclosure requires additional strength to maintain critical loading requirements, for example but not limited to seismic requirements (e.g., IEEE 693), lifting requirements, and transportation requirements, and increased thermal mass handling capabilities to accommodate a larger thermal mass during a thermal runaway event.

As such, it would be advantageous to provide a BESS including a BESS enclosure that supports battery racks having a larger footprint and the increased mass of the larger battery rack and multiple battery modules within the BESS enclosure, while maintaining critical loading requirements including, but not limited to seismic requirements e.g., IEEE 693), lifting requirements, and transportation requirements, and increasing thermal mass handling capabilities to accommodate a higher thermal mass during a thermal runaway event.

### SUMMARY

The concepts disclosed herein provide a battery energy storage system (BESS) including a BESS enclosure that supports a battery rack having a larger footprint and the increased mass of the larger battery rack and multiple battery modules within the BESS enclosure, while maintaining critical loading requirements including, but not limited to seismic requirements e.g., IEEE 693, lifting requirements, and transportation requirements, and increasing thermal mass handling capabilities to accommodate a higher thermal mass during thermal runaway events.

A BESS enclosure may include a main structure having a base weldment, a pair of opposing side weldments including a first/right side weldment and a second/left side weldment, and a top side weldment. A first/right inner insulation panel and a second/left inner insulation panel may be arranged adjacent to the first/right side weldment, and the second/left side weldment respectively. A rear panel may be arranged adjacent to the main structure, and a plurality of support crossbeams may be arranged within the main structure.

A battery rack may be arranged within the main structure of the BESS enclosure and may be attached to the main structure via a plurality of mounting connections, which may include battery rack to support crossbeam mounting connections and battery rack to weldment crossbeam mounting connections, each of which may include, for example but not limited to, an L-bracket and a fastener. A plurality of battery modules may be arranged within the battery rack supported within the BESS enclosure.

A BESS enclosure may include a top side weldment, a base weldment, a first/right side weldment, and a second/left side weldment.

Each of the top side weldment, the base weldment, the first/right side weldment, and the second/left side weldment may include a plurality of weldment crossbeams.

The first/right side weldment and the second/left side weldment each may include a top edge and a bottom edge respectively.

According to one aspect of the disclosure, each of the plurality of weldment crossbeams may include a hollow crossbeam.

According to one aspect of the disclosure, each of the plurality of weldment crossbeams may include a closed cross-section, for example but not limited to a rectangular cross-section, and/or a square cross-section.

Each of the base weldment, the first/right side weldment, the second/left side weldment and the top side weldment may include weldment crossbeams attached to one another via, for example but not limited to, welding, brackets/fasteners, and the like.

A top side weldment may include a front weldment crossbeam defining a front edge of the top side weldment, and a rear weldment crossbeam defining a rear edge of the top side weldment.

The top side weldment may include a center crossbeam arranged perpendicular to the front weldment crossbeam of the top side weldment and the rear weldment of the top side weldment.

A base weldment may include a front weldment crossbeam that may define a front edge of the base weldment, and a rear weldment crossbeam that may define a rear edge of the base weldment.

The base weldment may include at least two inner weldment crossbeams arranged parallel to the front weldment crossbeam of the base weldment and the rear weldment crossbeam of the base weldment.

A plurality of mounting connections for attaching a plurality of support crossbeams may be arranged within a main structure.

The plurality of support crossbeams may be attached to the main structure via a plurality of support crossbeam to weldment crossbeam mounting connections. Each of the plurality of support crossbeam to weldment crossbeam mounting connections may include, for example but not limited to, a double shear joint including a pair of mounting bracket plates and a fastener.

The plurality of support crossbeams may be arranged adjacent to the first/right side weldment.

According to one aspect of the disclosure, at least one of the plurality of support crossbeams may include a hollow crossbeam.

According to one aspect of the disclosure, the hollow crossbeam may include a closed cross-section, which may include, for example but not limited to, a rectangular cross-section, and/or a square cross-section.

According to one aspect of the disclosure, at least one of the plurality of support crossbeams may include a bolt-on crossbeam.

According to one aspect of the disclosure, the BESS enclosure may include a plurality of inner panels arranged within a main structure.

The plurality of inner panels may include a first/right inner insulation panel that may be arranged adjacent to an inner surface of the first/right side weldment, a second/left inner insulation panel that may be arranged adjacent to an inner surface of the second/left side weldment, and a rear panel.

The second/left inner insulation panel may include a top edge, a bottom edge, a rear edge, and a front edge.

According to one aspect of the disclosure, the second/left inner insulation panel may include a steel inner insulation panel.

A first/right inner insulation panel may include a panel portion, a top edge, a bottom edge, a rear portion, and a front portion. The front portion and the rear portion may be arranged perpendicular to the panel portion.

According to one aspect of the disclosure, the first/right inner insulation panel may include a steel inner insulation panel.

According to one aspect of the disclosure, the rear panel may be arranged adjacent to the main structure. The rear panel may include a bottom edge arranged adjacent to the rear edge of the base weldment, and a top edge arranged adjacent to the rear edge of the top side weldment.

According to one aspect of the disclosure, at least one of the plurality of inner panels may include a steel inner insulation panel.

According to one aspect of the disclosure, the rear panel may include a steel inner insulation panel.

According to another aspect of the disclosure, a battery energy storage system (BESS) may include at least one BESS enclosure, which may include a main structure, a rear panel that may be arranged adjacent to the main structure, a first inner insulation panel that may be arranged adjacent to an inner surface of the first side weldment, a second inner insulation panel that may be arranged adjacent to an inner surface of the second side weldment, a plurality of support crossbeams that may be arranged within the main structure, and a battery rack that may be arranged within the main structure.

The main structure may include a base weldment having a front edge and a rear edge, a pair of opposing side weldments including a first side weldment and a second side weldment, and a top side weldment having a front edge and a rear edge.

The rear panel may include a bottom edge that may be arranged adjacent to the rear edge of the base weldment, and a top edge that may be arranged adjacent to the rear edge of the top side weldment.

At least one of the first inner insulation panel and the second inner insulation panel may include a steel insulation panel.

Each of the plurality of support crossbeams that may be arranged within the main structure may include a hollow crossbeam having a closed cross-section.

By providing a BESS including a BESS enclosure that supports a battery rack having a larger footprint and the increased mass of the larger battery rack and multiple battery modules within the BESS enclosure, while maintaining critical loading requirements including, but not limited to seismic requirements e.g., IEEE 693, lifting requirements, and transportation requirements, and increasing thermal mass handling capabilities to accommodate a higher thermal mass during thermal runaway events.

The above features and advantages, and other features and attendant advantages of this disclosure, will be readily apparent from the following detailed description of illustrative examples and modes for carrying out the present disclosure when taken in connection with the accompanying drawings and the appended claims. Moreover, this disclosure expressly includes combinations and sub-combinations of the elements and features presented above and below.

### BRIEF DESCRIPTION OF THE DRAWINGS

The accompanying drawings, which are incorporated into and constitute a part of this specification, illustrate implementations of the disclosure which, taken together with the description, serve to explain the principles of the disclosure.

FIG. 1 schematically illustrates an isometric of a battery energy storage system (BESS) enclosure including a battery rack and battery modules in accordance with the present disclosure.

FIG. 1A schematically illustrates an isometric view of a BESS enclosure including a battery rack in accordance with the present disclosure.

FIG. 1B schematically illustrates a battery rack to crossbeam mounting connection for a BESS enclosure in accordance with the present disclosure.

FIG. 2 illustrates an isometric view of a BESS enclosure including a main structure having inner insulation panels in accordance with the present disclosure.

FIG. 2A schematically illustrates an isometric view of a BESS enclosure including a main structure having a plurality of weldment crossbeams in accordance with the present disclosure.

FIG. 3 schematically illustrates a top side weldment of a BESS enclosure in accordance with one aspect of the present disclosure.

FIG. 4 schematically illustrates a base weldment of a BESS enclosure in accordance with one aspect of the present disclosure.

FIG. 5 schematically illustrates a section of a right inner insulation panel of a BESS enclosure including a plurality of support crossbeams in accordance with one aspect of the present disclosure.

FIG. 5A schematically illustrates a double shear joint for attaching a support crossbeam to a main structure of a BESS enclosure in accordance with one aspect of the present disclosure.

FIG. 6 schematically illustrates a right inner insulation panel of a BESS enclosure in accordance with one aspect of the present disclosure.

FIG. 7 schematically illustrates a left inner insulation panel of a BESS enclosure in accordance with one aspect of the present disclosure.

FIG. 8 illustrates a rear panel of a BESS enclosure in accordance with one aspect of the present disclosure.

The appended drawings are not necessarily to scale and may present a somewhat simplified representation of various preferred features of the present disclosure as disclosed herein, including, for example, specific dimensions, orientations, locations, and shapes. Details adjacent to such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description in order to provide a thorough understanding of the embodiments disclosed herein, some embodiments may be practiced without some of these details. Moreover, for the purpose of clarity, certain technical material that is understood in the related art has not been described in detail in order to avoid unnecessarily obscuring the disclosure. Furthermore, the disclosure, as illustrated and described herein, may be practiced in the absence of an element that is not specifically disclosed herein.

The present disclosure is susceptible of embodiment in many different forms. Representative examples of the disclosure are shown in the drawings and described herein in detail as non-limiting examples of the disclosed principles. To that end, elements and limitations described herein, but not explicitly set forth in the claims, are not to be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, and the words “including,” “containing,” “comprising,” “having,” and the like shall mean “including without limitation.” Moreover, words of approximation such as “about,” “almost,” “substantially,” “generally,” “approximately,” etc., may be used herein in the sense of “at, near, or nearly at,” or “within 0-5% of,” or “within acceptable manufacturing tolerances,” or logical combinations thereof.

As used herein, the term “system” refers to mechanical and electrical hardware, software, firmware, electronic control componentry, processing logic, and/or processor device, individually or in combination, including without limitation: application specific integrated circuit (ASIC), an electronic circuit, a processor (shared, dedicated, or group) that executes one or more software or firmware programs, memory device(s) that electrically store software or firmware instructions, a combinatorial logic circuit, and/or other components that provide the described functionality.

As employed herein, terms such as "vertical", "horizontal", "left", "right", “upper”, “lower”, “top”, “bottom” and similar expressions are non-limiting terms that merely describe the various elements as illustrated in the Figures and are not intended to limit the scope of the disclosure.

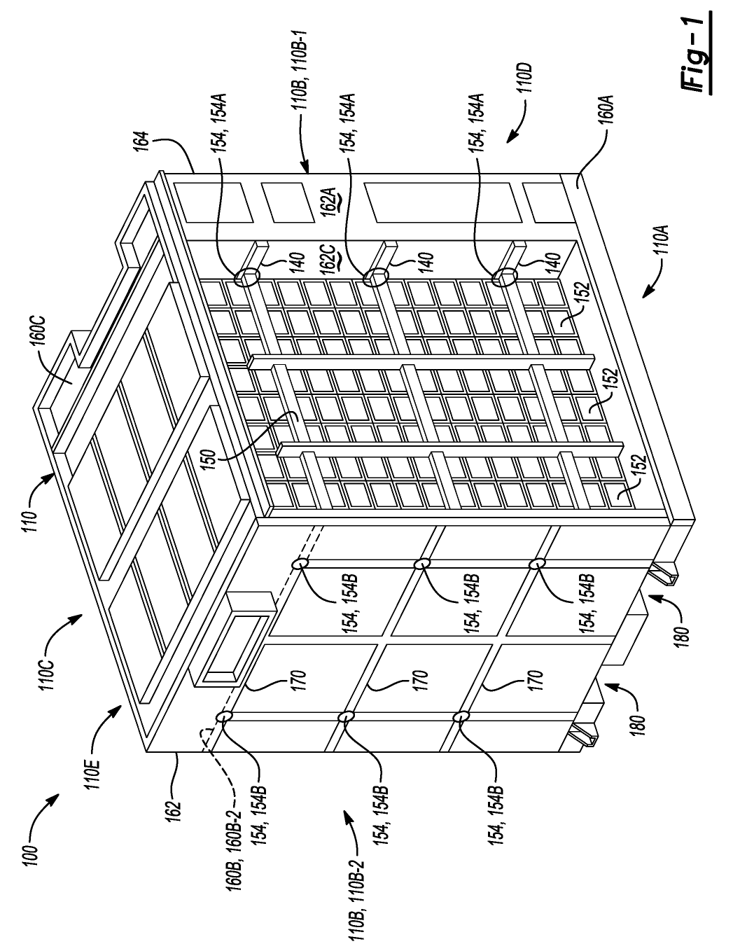

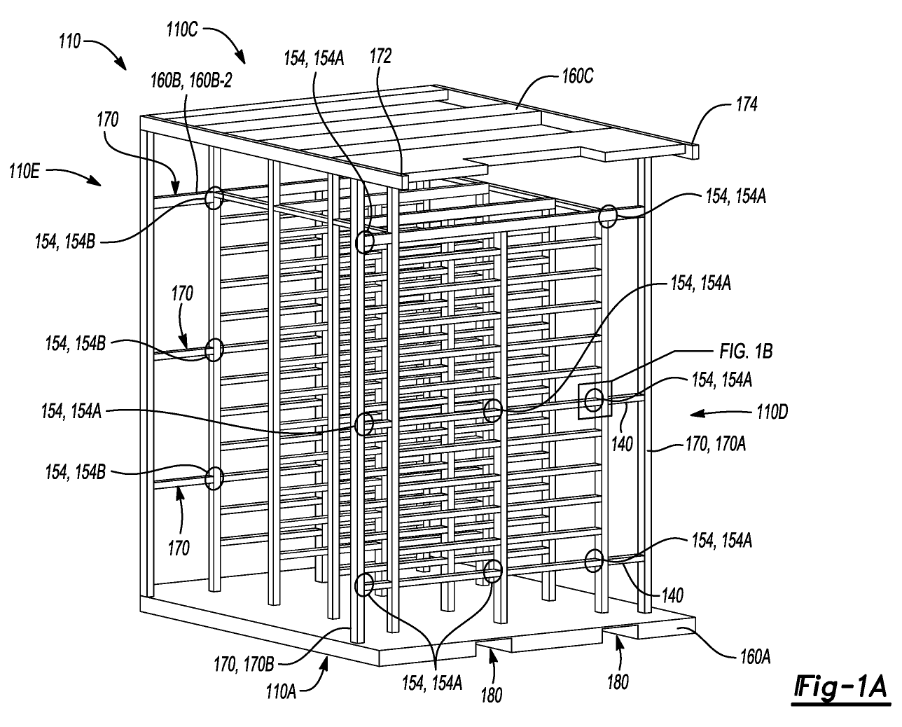

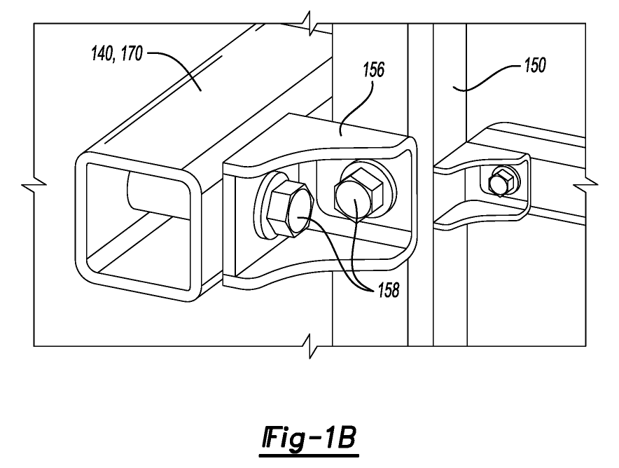

Referring to the drawings, wherein like reference numbers refer to the same or like components in the several Figures, FIG. 1 schematically illustrates an isometric view of a battery energy storage system (BESS) enclosure 100 for a BESS. The BESS enclosure 100 includes a main structure 110 and a rear panel 120. The main structure 110 includes a bottom side 110A, opposing sides 110B including a right side 110B-1 and a left side 110B-2, a top side 110C, a front side 110D, and a rear side 110E.

A plurality of support crossbeams 140, and a battery rack 150 including a plurality of battery modules 152 are arranged within the main structure 110. The plurality of support crossbeams 140 are arranged proximate to the right side 110B-1 of the main structure 110.

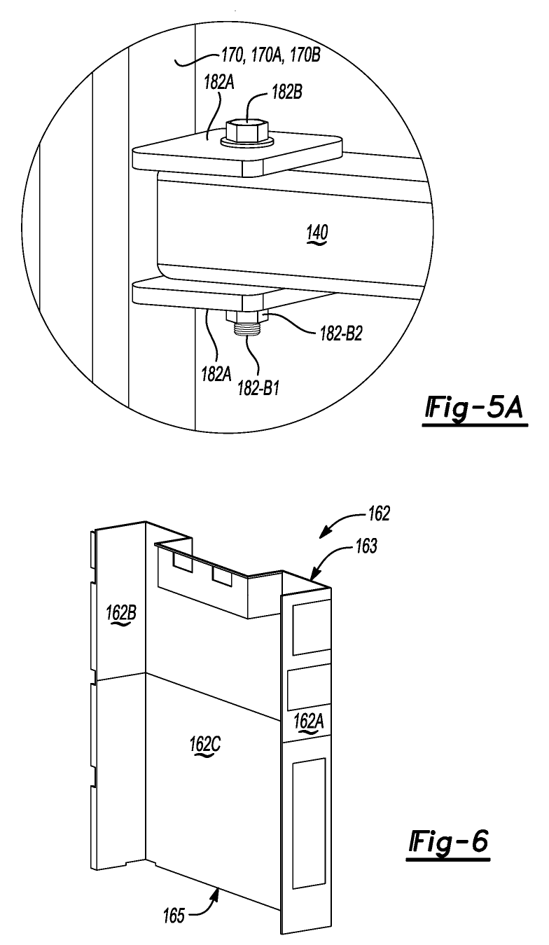

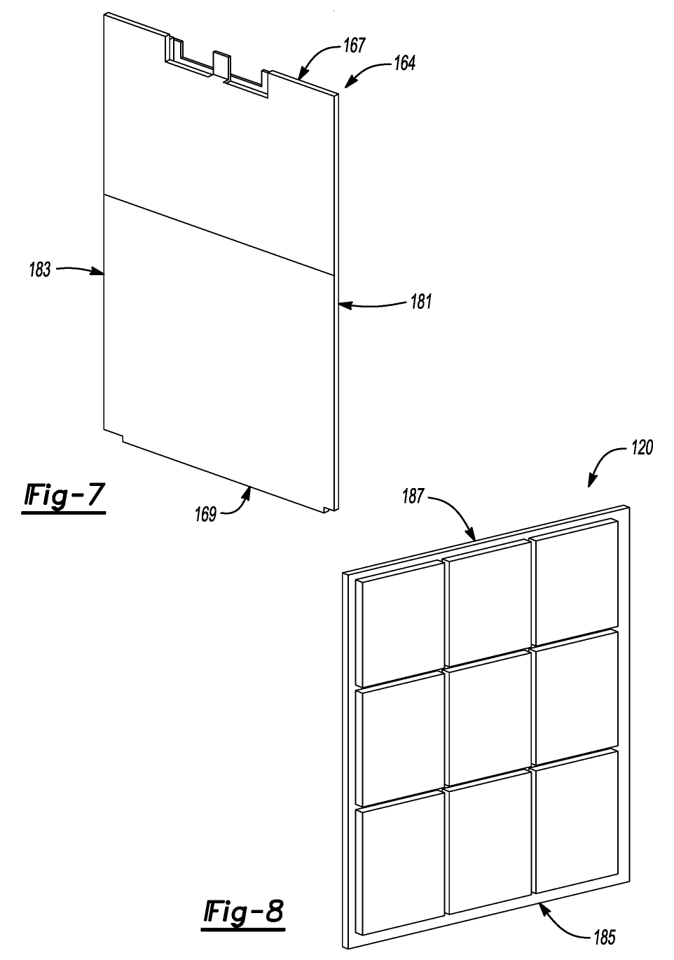

As illustrated in FIGS. 1, 1A and 1B, the BESS enclosure 100 includes the main structure 110 having a base weldment 160A arranged adjacent to the bottom side 110A of the main structure 110, a pair of opposing side weldments 160B including a first/right side weldment 160B-1 and a second/left side weldment 160B-2 arranged adjacent the opposing sides 110B of the main structure 110 including the right side 110B-1 and the left side 110B-2 of the main structure 110 respectively, and a top side weldment 160C arranged adjacent to the top side 110C of the main structure 110. A first/right inner insulation panel 162 (FIG. 6) and a second/left inner insulation panel 164 (FIG. 7) are arranged adjacent to the first/right side weldment 160B-1, and the second/left side weldment 160B-2 respectively. The rear panel 120 (FIG. 8) is arranged adjacent to the rear side 110E of the main structure 110, and a plurality of weldment crossbeams 170 are arranged within the main structure 110.

The battery rack 150 is arranged within the main structure 110 of the BESS enclosure 100, and attached to the main structure 110 via a plurality of battery rack mounting connections 154 including battery rack to support crossbeam mounting connections 154A and battery rack to weldment crossbeam mounting connections 154B, each of which include, for example but not limited to, an L-bracket 156 and fasteners 158 (FIG. 1B). A plurality of battery modules 152 is arranged within the battery rack 150 supported within the BESS enclosure 100.

It should be appreciated that while six (6) battery rack to weldment crossbeam mounting connections 154B are shown at the left side 110B-2 of the main structure 110, and eight (8) battery rack to support crossbeam mounting connections 154A are shown at the right side 110B-1 of the main structure 110, the number of either and/or both battery rack mounting connections 154 can be greater than and/or less than illustrated based on individual system requirements.

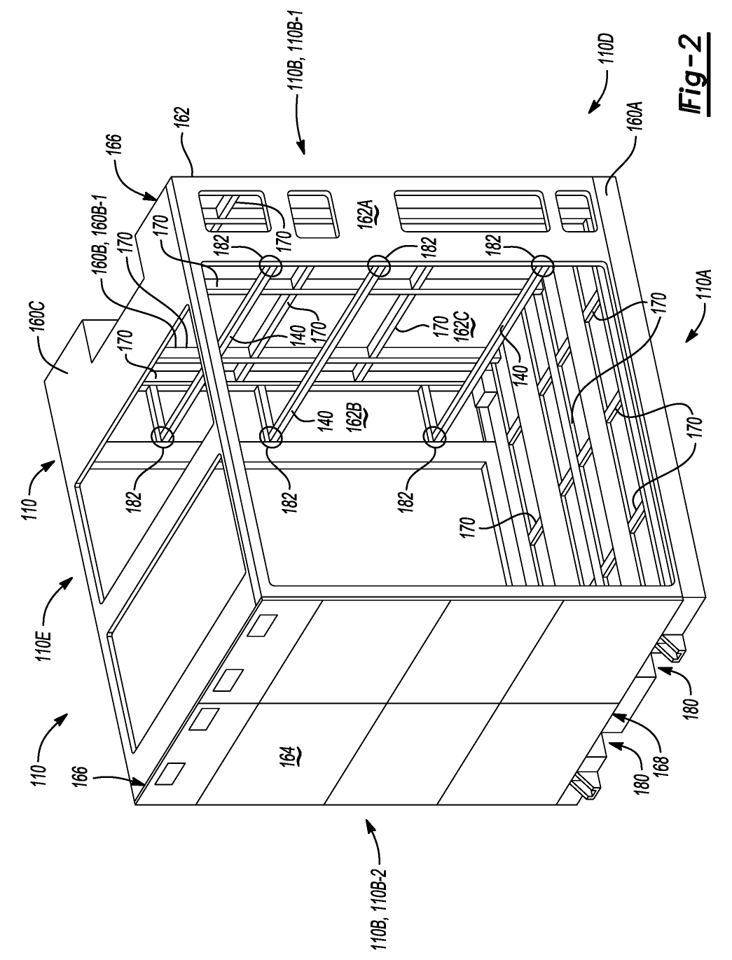

As illustrated in FIGS. 2 and 2A, a main structure 110 includes a bottom side 110A, opposing sides 110B including a right side 110B-1 and a left side 110B-2, a top side 110C, a front side 110D, and a rear side 110E.

A base weldment 160A is arranged adjacent to the bottom side 110A of the main structure 110, a pair of opposing side weldments 160B including a first/right side weldment 160B-1 and a second/left side weldment 160B-2 is arranged adjacent the opposing sides 110B of the main structure 110 including the right side 110B-1 and the left side 110B-2 of the main structure 110 respectively, and a top side weldment 160C is arranged adjacent to the top side 110C of the main structure 110.

Each of the top side weldment 160C, the base weldment 160A, the first/right side weldment 160B-1, and the second/left side weldment 160B-2 includes a plurality of weldment crossbeams 170.

The base weldment 160A includes a pair of forklift fork openings 180. The first/right side weldment 160B-1 and the second/left side weldment 160B-2 each respectively includes a top edge 166 and a bottom edge 168.

According to one aspect of the disclosure, each of the plurality of weldment crossbeams 170 includes a hollow crossbeam, i.e., having a hollow cross-section as schematically illustrated in FIG. 1B.

According to one aspect of the disclosure, each of the plurality of weldment crossbeams 170 includes a closed cross-section, for example but not limited to a rectangular cross-section, and/or a square cross-section.

As further illustrated in FIGS. 2A and 2B, each of the base weldment 160A, the first/right side weldment 160B-1, the second/left side weldment 160B-2, and the top side weldment 160C includes weldment crossbeams 170 attached to one another via, for example but not limited to, welding, brackets/fasteners, and the like.

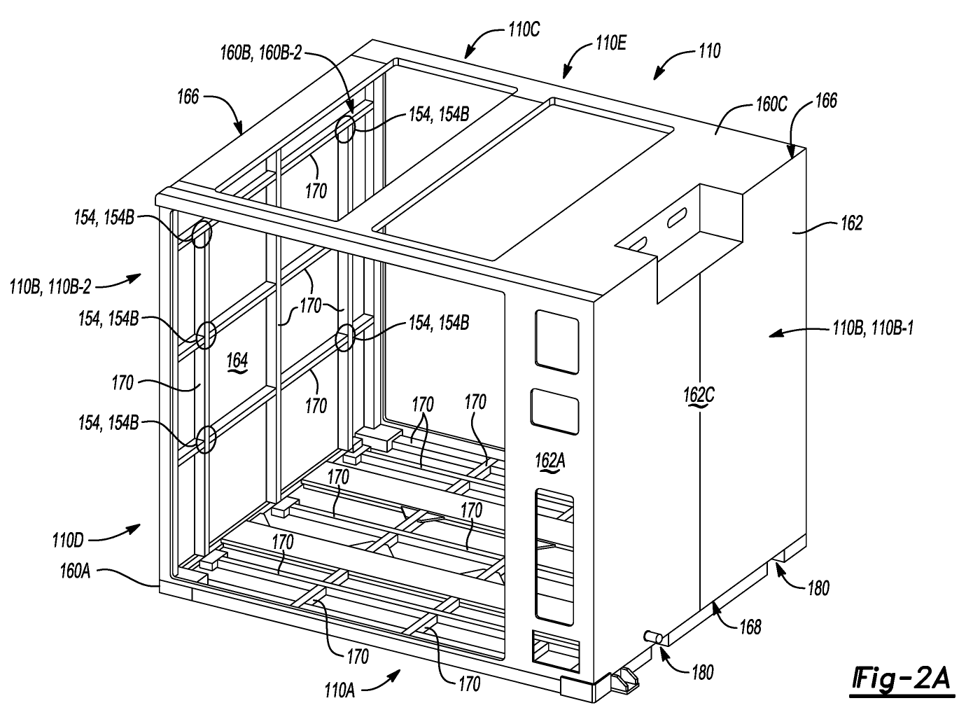

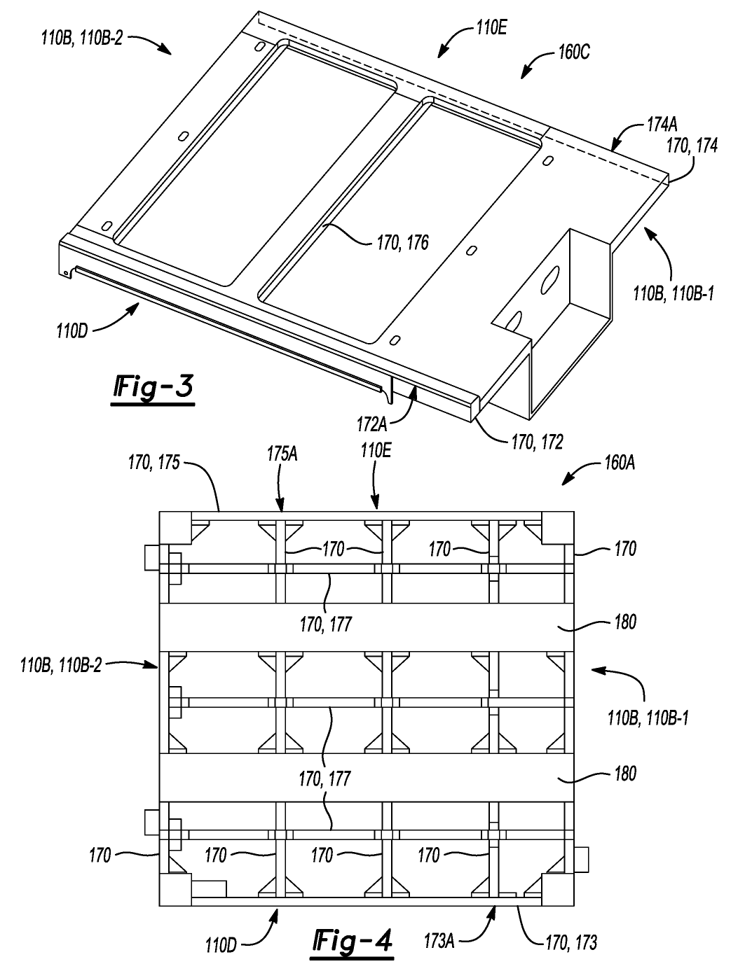

As illustrated in FIG. 3 with continued reference to FIGS. 1 – 2B, a top side weldment 160C includes a front weldment crossbeam 172 defining a front edge 172A of the top side weldment 160C, and a rear weldment crossbeam 174 defining a rear edge 174A of the top side weldment 160C.

According to one aspect of the disclosure, the top side weldment 160C includes a center top weldment crossbeam 176 arranged perpendicular to the front weldment crossbeam 172 of the top side weldment 160C and the rear weldment crossbeam 174 of the top side weldment 160C.

As illustrated in FIG. 4 with continued reference to FIGS. 1 – 2B, a base weldment 160A includes a front weldment crossbeam 173 defining a front edge 173A of the base weldment 160A, and a rear weldment crossbeam 175 defining a rear edge 175A of the base weldment 160A.

According to one aspect of the disclosure, the base weldment 160A includes at least two inner weldment crossbeams 177 arranged parallel to the front weldment crossbeam 173 of the base weldment 160A and the rear weldment crossbeam 175 of the base weldment 160A.

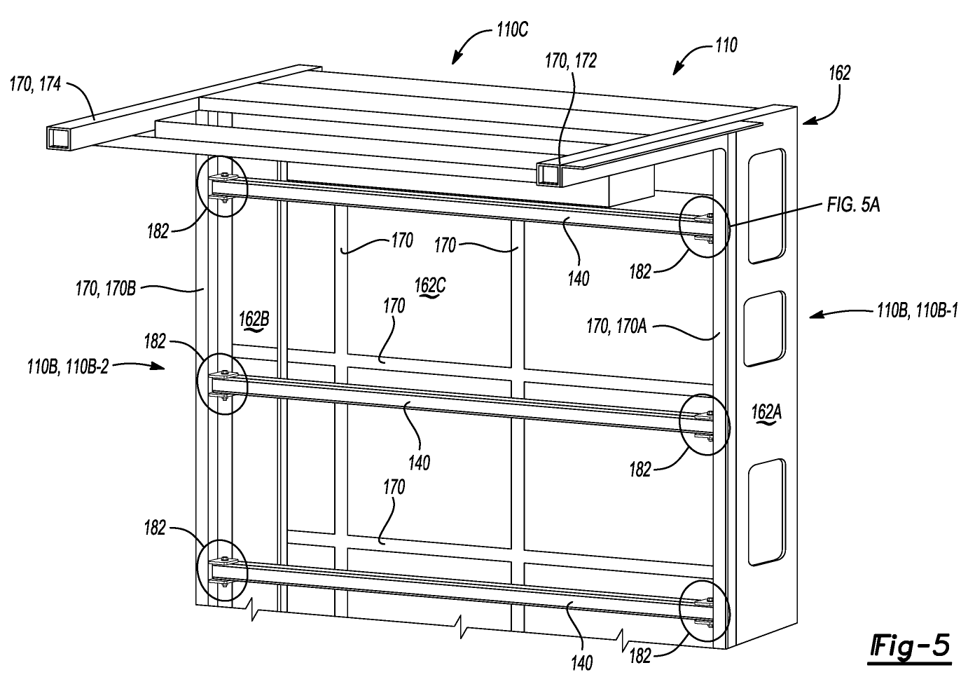

As illustrated in FIGS. 5 and 5A, with continued reference to FIGS. 1 – 2B, a plurality of support crossbeam to weldment crossbeam mounting connections, encircled at 182, for attaching the plurality of support crossbeams 140 to the main structure 110 are arranged within the main structure 110.

Each of the plurality of support crossbeams 140 is attached to a front weldment crossbeam 170A of the main structure 110, and a rear weldment crossbeam 170B of the main structure 110 respectively via the plurality of support crossbeam to weldment crossbeam mounting connections, encircled at 182, each of which include, for example but not limited to, a double shear joint including a pair of mounting bracket plates 182A and a fastener assembly 182B including a fastener or bolt 182B-1 and nut 182B-2, as schematically illustrated in FIG. 5A.

Each of the plurality of support crossbeams 140 is arranged adjacent to the first/right side weldment 160B-1, which may reduce battery rack side shift.

According to one aspect of the disclosure, at least one of the plurality of support crossbeams 140 includes a hollow crossbeam, i.e., having a hollow cross-section as schematically illustrated in FIG. 1B.

According to one aspect of the disclosure, the hollow crossbeam includes a closed cross-section, for example but not limited to a rectangular cross-section, and/or a square cross-section.

According to one aspect of the disclosure, at least one of the plurality of support crossbeams includes a bolt-on crossbeam.

It should be appreciated that while three (3) support crossbeams 140 are shown, at the right side 110B-1 of the main structure 110, the number of support crossbeams 140 can be greater than and/or less than illustrated based on individual system requirements.

It should be further appreciated that both the plurality of weldment crossbeams and the plurality of support crossbeams may be fabricated from “standard” closed section tubes, for example, hollow, steel crossbeams having a common rectangular cross-section, which adds strength and increased lateral stiffness to the BESS enclosure to maintain critical loading requirements including, but not limited to seismic requirements e.g., IEEE 693), lifting requirements, and transportation requirements, while reducing fabrication costs including but not limited to eliminating internal insulation typically required by open or C-section tubes.

Referring back to FIGS. 1 – 2A, a BESS enclosure includes a plurality of inner panels 120, 162, 164 arranged within the main structure 110.

The plurality of inner panels 120, 162, 164 includes a first/right inner insulation panel 162 (FIG. 6) arranged adjacent to an outer surface of the first/right side weldment 160B-1, a second/left inner insulation panel 164 (FIG. 7) arranged adjacent to an outer surface of the second/left side weldment 160B-2, and a rear panel 120 (FIG. 8).

As illustrated in FIG. 6, a first/right inner insulation panel 162 includes a panel portion 162C, a top edge 163, a bottom edge 165, a rear portion 162B, and a front portion 162A. The front portion 162A of the first/right inner insulation panel 162 and the rear portion 162B of the first/right inner insulation panel 162 are arranged perpendicular to the panel portion 162C of the first/right inner insulation panel 162.

According to one aspect of the disclosure, the first/right inner insulation panel 162 includes a steel inner insulation panel.

As illustrated in FIG. 7, a second/left inner insulation panel 164 includes a top edge 167, a bottom edge 169, a rear edge 181, and a front edge 183.

According to one aspect of the disclosure, the second/left inner insulation panel 164 includes a steel inner insulation panel.

As illustrated in FIG. 8 with continued reference to FIGS. 1 – 2A, a rear panel 120 is arranged adjacent to the rear side 110E of the main structure 110. The rear panel 120 includes a bottom edge 185 arranged adjacent to the rear edge 175A of the base weldment 160A, and a top edge 187 arranged adjacent to the rear edge 174A of the top side weldment 160C.

According to one aspect of the disclosure, at least one of the plurality of inner panels 120, 162, 164 includes a steel inner insulation panel.

According to one aspect of the disclosure, the rear panel 120 includes a steel inner insulation panel.

It should be appreciated that fabricating the inner panels including the first/right inner insulation panel, the second/left inner insulation panel, and/or the rear panel from steel, as opposed to traditional aluminum, provides increased thermal mass handling capabilities that can accommodate a higher thermal mass during thermal runaway events.

Therefore, by providing a BESS including a BESS enclosure that supports a battery rack having a larger footprint and the increased mass of the larger battery rack and multiple battery modules within the BESS enclosure, critical loading requirements including, but not limited to seismic requirements e.g., IEEE 693, lifting requirements, and transportation requirements can be maintained, while thermal mass handling capabilities can be increased to accommodate a higher thermal mass during thermal runaway events.

These and other attendant benefits of the present disclosure will be appreciated by those skilled in the art in view of the foregoing disclosure.

The detailed description and the drawings or figures are supportive and descriptive of the present teachings, but the scope of the present teachings is defined solely by the claims. While some of the best modes and other examples for carrying out the present teachings have been described in detail, various alternative designs and aspects of the disclosure exist for practicing the present teachings defined in the appended claims.

What is claimed is:

1. A battery energy storage system (BESS) comprising:
at least one BESS enclosure including:
a main structure including:
a base weldment having a front edge and a rear edge;
a pair of opposing side weldments including a first side weldment and a second side weldment; and
a top side weldment having a front edge and a rear edge; and
a rear panel arranged adjacent to the main structure, the rear panel having a bottom edge and a top edge, wherein the bottom edge of the rear panel is arranged adjacent to the rear edge of the base weldment, and the top edge of the rear panel is arranged adjacent to the rear edge of the top side weldment;
a plurality of support crossbeams arranged within the main structure; and
a battery rack arranged within the main structure.

2. The BESS as recited in claim 1, wherein the main structure includes a plurality of weldment crossbeams, each of the plurality of weldment crossbeams having a rectangular cross-section.

3. The BESS as recited in claim 1, wherein the base weldment includes a front weldment crossbeam defining the front edge of the base weldment, and a rear weldment crossbeam defining the rear edge of the base weldment.

4. The BESS as recited in claim 1, wherein the base weldment includes at least two inner weldment crossbeams arranged parallel to the front weldment crossbeam of the base weldment and the rear weldment crossbeam of the base weldment.

5. The BESS as recited in claim 1, wherein the top side weldment includes a front weldment crossbeam defining the front edge of the top side weldment and a rear weldment crossbeam defining the rear edge of the top side weldment.

6. The BESS as recited in claim 1, wherein the top side weldment includes a center crossbeam arranged perpendicular to the front weldment crossbeam of the top side weldment and the rear weldment crossbeam of the top side weldment.

7. The BESS as recited in claim 1, wherein the main structure includes a plurality of mounting connections for attaching the plurality of support crossbeams within the main structure.

8. The BESS as recited in claim 1, wherein the plurality of support crossbeams is arranged adjacent to the first side weldment.

9. The BESS as recited in claim 1, wherein at least one of the plurality of support crossbeams includes a hollow crossbeam.

10. The BESS as recited in claim 9, wherein the hollow crossbeam includes a closed cross-section.

11. The BESS as recited in claim 10, wherein the closed cross-section includes a rectangular cross-section.

12. The BESS as recited in claim 10, wherein the closed cross-section includes a square cross-section.

13. The BESS as recited in claim 1, wherein at least one of the plurality of support crossbeams includes a bolt-on crossbeam.

14. The BESS as recited in claim 1, wherein the main structure includes a plurality of inner panels arranged within the main structure.

15. The BESS as recited in claim 14, wherein the plurality of inner panels includes a first inner insulation panel arranged adjacent to an inner surface of the first side weldment, and a second inner insulation panel arranged adjacent to an inner surface of the second side weldment.

16. The BESS as recited in claim 14, wherein at least one of the plurality of inner panels includes a steel inner insulation panel.

17. The BESS as recited in claim 1, wherein the rear panel includes a steel inner insulation panel.

18. A battery energy storage system (BESS) comprising:
at least one BESS enclosure including:
a main structure including:
a base weldment having a front edge, and a rear edge;
a pair of opposing side weldments including a first side weldment and a second side weldment; and
a top side weldment having a front edge and a rear edge; and
a rear panel arranged adjacent to the main structure, the rear panel having a bottom edge and a top edge, wherein the bottom edge of the rear panel is arranged adjacent to the rear edge of the base weldment, and the top edge of the rear panel is arranged adjacent to the rear edge of the top side weldment;
a first inner insulation panel arranged adjacent to an inner surface of the first side weldment;
a second inner insulation panel arranged adjacent to an inner surface of the second side weldment;
a plurality of support crossbeams arranged within the main structure; and
a battery rack arranged within the main structure.

19. The BESS as recited in claim 18, wherein at least one of the first inner insulation panel and the second inner insulation panel includes a steel insulation panel.

20. The BESS as recited in claim 18, wherein each of the plurality of support crossbeams arranged within the main structure includes a hollow crossbeam having a closed cross-section.
